(19) United States
(12) Patent Application Publication
(10) Pub. No.: US 2009/0299678 A1
(43) Pub. Date: Dec. 3, 2009

(54) METHOD AND APPARATUS FOR DETERMINING A PRODUCT LOADING PLAN FOR A TESTING SYSTEM

(76) Inventor: PENG QU, Austin, TX (US)

Correspondence Address: WILLIAMS, MORGAN & AMERSON, 10333 RICHMOND, SUITE 1100, HOUSTON, TX, 77042, US

(21) Appl. No.: 12/127,306

(22) Filed: May 27, 2008

(51) Int. Cl. G01R 31/28

(52) U.S. Cl. 702/119

(57) ABSTRACT

A method for determining a loading plan for a testing system includes determining demand quotas for a plurality of devices to be processed through the testing system. Each demand quota specifies a number of required devices and an associated performance specification. A bin classification distribution for devices processed through the testing system is estimated. Each device has an associated product type. Each bin classification indicates a performance grade of the associated devices. A number of devices matching each performance specification exiting the testing system is estimated based on the bin classification distribution. A device loading plan specifying a count of devices for each of a plurality of the product types to be dispatched to the testing system to provide the estimated number of devices matching each performance specification exiting the testing system to substantially meet the demand quota associated with each performance specification is determined.

### CROSS-REFERENCE TO RELATED APPLICATIONS

Not applicable.

### BACKGROUND OF THE DISCLOSURE

The disclosed subject matter relates generally to manufacturing and, more particularly, to a method and apparatus for determining a product loading plan for a testing system.

There is a constant drive within the semiconductor industry to increase the quality, reliability and throughput of integrated circuit devices, e.g., microprocessors, memory devices, and the like. This drive is fueled by consumer demands for higher quality computers and electronic devices that operate more reliably. These demands have resulted in a continual improvement in the manufacture of semiconductor devices, e.g., transistors, as well as in the manufacture of integrated circuit devices incorporating such transistors. Additionally, reducing the defects in the manufacture of the components of a typical transistor also lowers the overall cost per transistor as well as the cost of integrated circuit devices incorporating such transistors.

Generally, a set of processing steps is performed on a wafer using a variety of processing tools, including photolithography steppers, etch tools, deposition tools, polishing tools, rapid thermal processing tools, implantation tools, etc. During the fabrication process various events may take place that affect the performance of the devices being fabricated. That is, variations in the fabrication process steps result in device performance variations. Factors, such as feature critical dimensions, doping levels, contact resistance, particle contamination, etc., all may potentially affect the end performance of the device.

After fabrication of the devices is complete, each wafer is subjected to preliminary functional tests, commonly referred to as final wafer electrical tests (FWET) that evaluate test structures on the wafer and SORT tests that evaluate each die. Wafers that pass these tests are then cut to singulate the individual die, which are then packed in substrates. Packed die are then subjected to additional tests against the specification of customers' orders to determine performance characteristics such as maximum operating speed, power, caches, etc.

Exemplary tests include initial class tests (ICL) that is a preliminary test for power and speed. ICL testing is usually followed by burn-in (BI) and post burn-in (PBI) tests that test packaged die under specified temperature and/or voltage stress and test die functionality. Then, packaged die with different characteristics go through system-level tests (SLT) in which they are tested against customer requirements on specific electrical characteristics. In SLT, packaged die are tested in an actual motherboard by running system-level tests (e.g., variance test programs). After completion of the testing, the devices are fused, marked, and packed to fill customer orders. This back-end processing is commonly referred to as the test, mark, pack (TMP) process.

TMP is the last process in semiconductor manufacturing before finished packages can be shipped to customers. The characteristics of the TMP process are high product mix and high volume. Even for the same product type, different variations may be present depending on specific customer requirements with respect to power, speed, etc. To satisfy these differing requirements, an extremely large number of processing specifications are used to define different temperatures, test programs, etc.

In general, semiconductor devices are tested and graded to determine their performance characteristics. Logical bins are defined that group devices with similar operating characteristics. Usually devices tested under specific test environments will exhibit different performance metrics (e.g., different speed, power, voltage, etc.). By classifying and grouping the materials to different bins, a better understanding may be achieved with respect to how to meet the requirements associated with particular order part numbers (OPN) that customers typically use to order devices. A bin may be thought of as a preliminary performance grade, and an OPN may be thought of as a performance specification.

For example, after PBI devices may be separated into bins 1, 2, and 3 under a certain test suite A. Bin 1 may be qualified for desktop chips with 65 watt, 2.9 GHZ speed, 1.325 voltage. Bin 2, may only show performance to support 2.8 GHZ, and Bin 3 may be 2.6 GHZ. If there are orders based on an OPN for 2.9 GHZ, only materials in bin 1 will be qualified, as the devices in bins 2 and 3 have lower speeds. However, if the orders specify 2.6 GHZ, then not only materials from bin 3 may be used to supply the demand. Devices from both bins 1 and 2 can also be used after a down-bin. A down-bin tests the device to a lower performance specification, and the devices are fused, marked, and sold as lower speed. Another scenario where down-binning occurs is when a device is tested to a high speed specification associated with a particular OPN and fails. However, the device still qualifies when tested using a lower speed test to qualify for a different OPN. For example, if a device is tested against a 2.9 GHZ OPN fails, the same device can be re-tested against test suites for 2.7 GHZ OPNs.

In a conventional test line, the devices are binned after PBI and then matched to various OPNs using system level testing. If a device fails, it is removed from the test flow and reinserted at a later point to attempt qualification at a less stringent OPN. This rerouting typically adds several days to the processing flow for the affected device.

A more recently introduced type of testing tool is a hybrid system test (HST) tool that combines the functionality of an ATE tester for burn-in testing and post-burn-in testing, and a system level tester for system level testing. A hybrid system tester receives packaged devices, grades them into bins, and then and tests them against the performance specifications of specific order part numbers (OPNs) that define customer requirements. If a part fails, the hybrid system tester can automatically down-bin the device and test it against a less stringent OPN without interrupting the flow and incurring a reinsertion delay.

Compared to the previous approach, hybrid system testing offers a significant improvement with respect to test time. However, such testing adds extra complexities to planning. In the previous approach, after devices are binned out to grades after PBI, planners make the marking decisions (i.e., device to OPN mapping) based on the actual bins. There are detailed production specifications listing all the qualified bins after PBI to satisfy a specific OPN. With hybrid system testers, planners make the device-to-OPN mapping decisions with no knowledge of the possible bin-outs, as they are automated in the test suite.

The capability of the hybrid system tester to automatically down-bin devices adds an extra level of planning uncertainty. Yield fluctuation can also impact the final device distribution. With all these uncertainties, the fixed OPN mapping in the test suites can result in either over-production or shortage. The hybrid system tester may qualify the devices for OPNs that have no demand. This material is placed into inventory and may never be used. Moreover, devices that were not actually needed were ordered from the assembly facility and incurred the cost of packaging. If a device is ultimately to be kept in inventory, it is less expensive to keep the device as inventory in die form as opposed to packaged form.

This section of this document is intended to introduce various aspects of art that may be related to various aspects of the disclosed subject matter described and/or claimed below. This section provides background information to facilitate a better understanding of the various aspects of the disclosed subject matter. It should be understood that the statements in this section of this document are to be read in this light, and not as admissions of prior art. The disclosed subject matter is directed to overcoming, or at least reducing the effects of, one or more of the problems set forth above.

### BRIEF SUMMARY OF THE DISCLOSURE

The following presents a simplified summary of the disclosed subject matter in order to provide a basic understanding of some aspects thereof. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

One aspect of the disclosed subject matter is seen in a method for determining a loading plan for a testing system. The method includes determining demand quotas for a plurality of devices to be processed through the testing system. Each demand quota specifies a number of required devices and an associated performance specification. A bin classification distribution for devices processed through the testing system is estimated. Each device has an associated product type. Each bin classification indicates a performance grade of the associated devices. A number of devices matching each performance specification exiting the testing system is estimated based on the bin classification distribution. A device loading plan specifying a count of devices for each of a plurality of the product types to be dispatched to the testing system to provide the estimated number of devices matching each performance specification exiting the testing system to substantially meet the demand quota associated with each performance specification is determined.

Another aspect of the disclosed subject matter is seen in an apparatus for determining a loading plan for a testing system including at least one testing tool operable to test integrated circuit devices. The apparatus includes a loading unit operable to determine demand quotas for a plurality of devices to be processed through the testing system, each demand quota specifying a number of required devices and an associated performance specification; estimate a bin classification distribution for devices processed through the testing system, each device having an associated product type, each bin classification indicating a performance grade of the associated devices; estimate a number of devices matching each performance specification exiting the testing system based on the bin classification distribution; and generate a device loading plan specifying a count of devices for each of a plurality of the product types to be dispatched to the testing system to provide the estimated number of devices matching each performance specification exiting the testing system to substantially meet the demand quota associated with each performance specification.

### BRIEF DESCRIPTION OF THE SEVERAL VIEWS OF THE DRAWINGS

The disclosed subject matter will hereafter be described with reference to the accompanying drawings, wherein like reference numerals denote like elements, and:

FIG. 1 is a simplified block diagram of a manufacturing system in accordance with one embodiment of the disclosed subject matter; and

FIG. 2 is a simplified flow diagram of a method for determining product loading for a testing system in accordance with another embodiment of the disclosed subject matter.

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the spirit and scope of the disclosed subject matter as defined by the appended claims.

### DETAILED DESCRIPTION

One or more specific embodiments of the disclosed subject matter will be described below. It is specifically intended that the disclosed subject matter not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the disclosed subject matter unless explicitly indicated as being “critical” or “essential.”

The disclosed subject matter will now be described with reference to the attached figures. Various structures, systems and devices are schematically depicted in the drawings for purposes of explanation only and so as to not obscure the disclosed subject matter with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Portions of the disclosed subject matter are presented in terms of software, or algorithms and symbolic representations of operations on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” or “accessing” or “displaying” or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices. Note also that the software implemented aspects of the disclosed subject matter are typically encoded on some form of program storage medium or implemented over some type of transmission medium. The program storage medium may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The disclosed subject matter is not limited by these aspects of any given implementation.

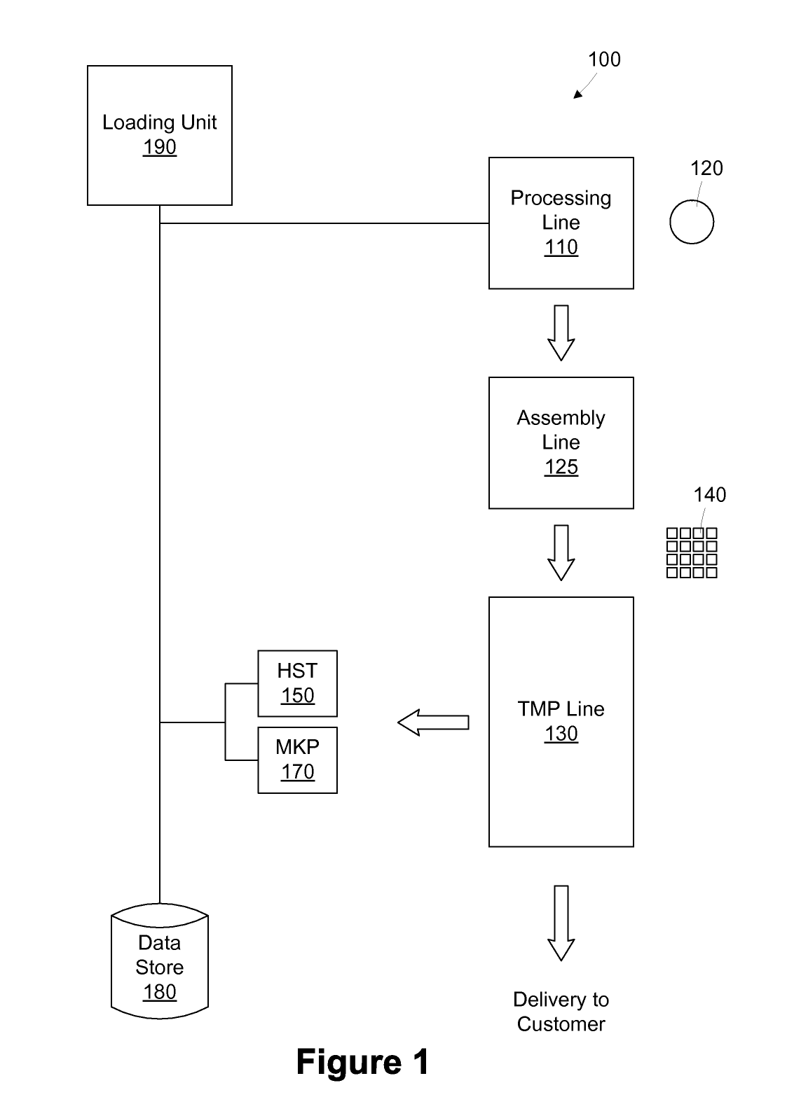

Referring now to the drawings wherein like reference numbers correspond to similar components throughout the several views and, specifically, referring to FIG. 1, the disclosed subject matter shall be described in the context of an illustrative manufacturing system 100. The manufacturing system 100 includes a processing line 110 for fabricating wafers 120, an assembly line 125 for cutting wafers and packing devices 140, a test, mark, pack (TMP) line 130 for processing the devices 140, a hybrid system tester (HST) 150, a mark and pack tool (MKP) 170, a data store 180, and a loading unit 190. In the illustrated embodiment, the TMP line 130 employs the hybrid system testers 150 to combine the functionality of conventional ATE testers and system level testers to reduce test time. Hence, a hybrid system test tool 150 performs burn-in, post-burn-in, and system level testing. Generally, the loading unit 190 attempts to determine the quantities of products that are ordered from the assembly line 125 and processed in the TMP line 130 to meet anticipated demand for various order part numbers (OPN). The loading unit 190 also determines the test suites employed by the hybrid system testers 150 and the products that are run through each test suite.

In the illustrated embodiment, wafers 120 are processed by the processing line 110 to fabricate die thereon. The processing line 110 may include a variety of process tools and/or metrology tools, which may be used to process and/or examine the wafers to fabricate the semiconductor devices. For example, the process tools may include photolithography steppers, etch tools, deposition tools, polishing tools, rapid thermal anneal tools, ion implantation tools, and the like. The process metrology tools may include thickness measurement tools, scatterometers, ellipsometers, scanning electron microscopes, and the like. Techniques for processing the wafers 120 are well known to persons of ordinary skill in the art and therefore will not be discussed in detail herein for clarity and to avoid obscuring the present subject matter. Although a single wafer 120 is pictured in FIG. 1, it is to be understood that the wafer 120 is representative of a single wafer as well as a group of wafers, e.g. all or a portion of a wafer lot that may be processed in the processing line 110.

After the wafers 120 have been processed in the processing line 110 to fabricate the die, certain metrology tools, such as sort or final wafer electrical test (FWET) tools may be employed to collect electrical performance data while the wafer is still uncut. Sort metrology employs a series of probes to electrically contact pads on the completed die to perform electrical and functional tests. For example, a sort metrology tool may measure voltages and/or currents between various nodes and circuits that are formed on the wafer 120. Exemplary sort parameters measured include, but are not limited to, clock search parameters, diode characteristics, scan logic voltage, static I_{DD}, minimum V_{DD}, power supply open short characteristics, and ring oscillator frequency, etc. The particular sort parameters selected may vary depending on the application and the nature of the device formed on the die. Final wafer electrical testing (FWET) entails parametric testing of discrete structures like transistors, capacitors, resistors, interconnects and relatively small and simple circuits, such as ring oscillators. It is intended to provide a quick indication as to whether or not the wafer is within basic manufacturing specification limits. Wafers that exceed these limits are typically discarded so as to not waste subsequent time or resources on them.

After the die on the wafer 120 have completed preliminary testing, the wafers 120 are cut in the assembly line 125 to singulate the die. Typically, orders are placed from the assembly line 125 for feeding the TMP line 130. Each ordered die is then each mounted to a package, resulting in the devices 140. The loading unit 190 attempts to minimize the number of ordered die to reduce per unit cost. Once a die has been packaged, it cannot be reworked. Hence, minimizing the number of ordered die, while meeting customer demand increases the efficiency of the processing line 110.

The hybrid system testers 150 then subject the devices 140 to various testing programs to grade the devices and verify full functionality. Although only a single hybrid system tester 150 is illustrated, an actual implementation will involve multiple hybrid system testers 150. In addition, a particular hybrid system tester 150 may test multiple devices 140 in parallel. The data store 180 houses information related to the testing of the devices 140 over the plurality of test program runs, or insertions.

One particular useful function of a hybrid system tester 150 is to automatically down-bin tested devices 140. The test suite of a hybrid system tester 150 bins the devices to determine a preliminary performance grade and then attempts to determine if a particular device 140 meets the performance specification for a particular OPN. If the device 140 fails an initial test, the hybrid system tester 150 automatically tests the parts against another OPN. The hybrid system tester 150 employs a test hierarchy to eventually match the device 140 to an OPN that it passes or it indicates that the device 140 is defective.

The loading unit 190 employs an optimization technique that attempts to determine the minimum number of devices 140 to order from the assembly line 125 and still be able to meet anticipated demand for various OPNs. The loading unit 190 employs a linear mixed-integer programming model for determining the required loading. In such an optimization based approach, solutions are driven by a plurality of objectives. Constraints are defined that serve as conditions to narrow down the solution scope. With a commercially or publicly available solver, a linear (i.e., either integer or non-integer) solution can be identified within the solution scope. For example, the OSL solver offered by IBM, Corporation is a commercially available software tool that may be used. For purposes of the following description, the following notation list provided in Table 1 identifies symbols used in the following objective and constraint equations.

TABLE 1
Notation
Sets

| | |
|---|---|
| P | Set of devices (i.e., or products) |
| T | Set of test suites |
| B | Set of bins |
| O | Set of order part numbers (OPN) |

Parameters

| | |
|---|---|
| Gₒ | Build target for OPN o ∈ O. This parameter specifies the |
| | expected demand for various OPNs over the scheduling |
| | interval (e.g., week, day, or shift). |
| δ_{p,b,t,o} | Qualified Bill of Material (BOM). This Boolean parameter |
| | indicates that for a product p ∈ P, tested using a test suite |
| | t ∈ T, that bins out to bin b ∈ B, it will be qualified to build a |
| | particular OPN o ∈ O |
| λ_{p,o1,o2} | Valid down bin for high speed OPN o1 ∈ O to low speed |
| | OPN o2 ∈ O(o1 ≠ o2) if product p ∈ P. This Boolean |
| | parameter indicates that a particular product associated |
| | with a first OPN can be down-binned to a second OPN. |
| η_{p,b,t} | Bin distribution for product p ∈ P, if using test suite t ∈ T, |
| | the bin out percentage for bin b ∈ B. This parameter |
| | represents an estimated bin distribution that relates |
| | products to bins. The distribution may use a prediction or |
| | historical projection. |
| η_{p,o}* | OPN yield for product p ∈ P. This yield parameter indicates |
| | an expected yield of OPNs for a particular product. The |
| | distribution may use a prediction or historical projection. |
| Sₚ | Supply for product p ∈ P. This parameter represents the |
| | number of devices of product type p that are available for |
| | order from the assembly line 125. |
| μ_{p,t} | Boolean to indicate whether product p ∈ P is qualified to |
| | run test suite t ∈ T. This parameter maps products to valid |
| | test suites. |

Variables

| | |
|---|---|
| L_{p,t} | Device loading plan for product p ∈ P using test suite t ∈ T |
| D_{p,o1,o2} | Estimated volume of product p ∈ P that successfully passes |
| | the test for OPN o1 ∈ O, but are down-binned to support |
| | demand of OPN o2 ∈ O (o1 ≠ o2). |
| D_{p,o1,o2}′ | Estimated volume of product p ∈ P fails the test for OPN |
| | o1 ∈ O that are down-binned to test for OPN |
| | o2 ∈ O(o1 ≠ o2). |
| σ_{p,o} | OPN test-in volume of product p ∈ P used to supply OPN |
| | o ∈ O based on different bin outs. The test-in volume |
| | represents an interim volume of devices that have |
| | completed the PBI portion of the HST and await system |
| | level testing. |

The loading unit 190 employs the following objective function to minimize loadings of products across the test suites. Again, by minimizing the loading, only those products needed to meet demand ore ordered from the assembly line 125 and provided to the TMP line 130.

$$Minimize {\sum }_{p ∈ P , t ∈ T} {L}_{p , t} \qquad ( 1 )$$

The loading unit 190 employs a series of constraints in attempting to determine the loading that optimizes Equation 1.

A first constraint specifies that the loading count for all products, p∈P, should be less than or equal to the available materials.

$$\begin{matrix}{\sum }_{t ∈ T} {L}_{p , t} \leq {S}_{p} & ∀ p ∈ P\end{matrix} \qquad ( 2 )$$

A second constraint generates a test-in volume by multiplying the loading, L, by the expected bin distribution, η, and the BOM mapping, δ. The test-in volume represents the number of devices in each bin classification after PBI and prior to system level testing.

$${σ}_{p , o} = {\sum }_{b ∈ B , t ∈ T} {η}_{p , b , t} {L}_{p , t} {δ}_{p , b , t , o} \qquad ( 4 )$$

A third constraint limits the failed materials that are eligible for down-binning to the total number of failed materials. The failed materials are determined using the test-in volume estimate, σ_{p,0}, and the expected OPN yield, η_{p,0}*.

$$\begin{matrix}{\sum }_{o 2 ∈ O , {λ}_{p , o , o 2} = 0} {D}_{p , o , o 2}^{′} \leq {σ}_{p , o} ( 1 - {η}_{p , o}^{*} ) & ∀ p ∈ P , ∀ o ∈ O\end{matrix} \qquad ( 5 )$$

Similarly, the good devices eligible for down-bin cannot exceed the available good materials, based on the test-in volume estimate, σ_{p,0}, and the expected OPN yield, η_{p,0}*.

$$\begin{matrix}{\sum }_{o 2 ∈ O , {λ}_{p , o , o 2} = 0} {D}_{p , o , o 2} \leq {σ}_{p , o} {η}_{p , o}^{*} & ∀ p ∈ P , ∀ o ∈ O\end{matrix} \qquad ( 6 )$$

Another constraint defines a condition that all estimated good materials must meet or exceed the estimated demand.

$${\sum }_{p ∈ P} ( {σ}_{p , o} {η}_{p , o}^{*} - {\sum }_{o 2 ∈ O ; o \neq o 2} {D}_{p , o , o 2} + {\sum }_{o 1 ∈ O ; o \neq o 1} {D}_{p , o 1 , o} + {\sum }_{o 3 ∈ O ; o \neq o 3} {D}_{p , o 3 , o}^{′} ) \geq {G}_{o} o ∈ O \qquad ( 3 )$$

The first term represents the expected OPN yields for the products. The second term represents the tested good devices for a particular OPN that are down-binned to a different OPN to support demand for the other OPN. The third term represents the tested good devices for a different OPN that are down-binned to meet demand for the subject OPN. The fourth term represents the volume of devices from a different OPN that do not pass and are down-binned and pass for the subject OPN.

Another constraint specifies that a loading cannot be generated for a product p∈P and a test suite t∈T if the product is not qualified to run the test suite.

L_{p,t}=0 ∀p∈P, ∀t∈T, μ_{p,t}=0 (7)

Also, down-bins are not allowed for products that are not qualified for the different OPN. This applies to demand driven down-bins, D, and performance driven down-bins, D′.

$$\begin{matrix}{\sum }_{{λ}_{p , o 1 , o 2} = 0} {D}_{p , o 1 , o 2} = 0 & ∀ p ∈ P , ∀ o 1 , o 2 ∈ O , o 1 \neq o 2\end{matrix} \qquad ( 8 )$$

$$\begin{matrix}{\sum }_{{λ}_{p , o 1 , o 2} = 0} {D}_{p , o 1 , o 2}^{′} = 0 & ∀ p ∈ P , ∀ o 1 , o 2 ∈ O , o 1 \neq o 2\end{matrix} \qquad ( 9 )$$

The loading unit 190 optimizes the loading using Equation 1 to minimize the loading subject to the constraints defined in Equations 2-9. The resulting loading specifies product quantities to be ordered from the assembly line 125 and also defines which products are to be tested according to particular test suites. By accounting for the automatic down-binning performed by the hybrid system testers 150 and allowing for demand driven down-binning, the output distribution of the TMP line 130 with respect to OPN targets should more effectively track demand. This improved performance reduces devices that are ordered from the assembly line 125, thereby reducing unit cost, and also reduces the number of completed devices that are not needed to support demand, thereby reducing inventory.

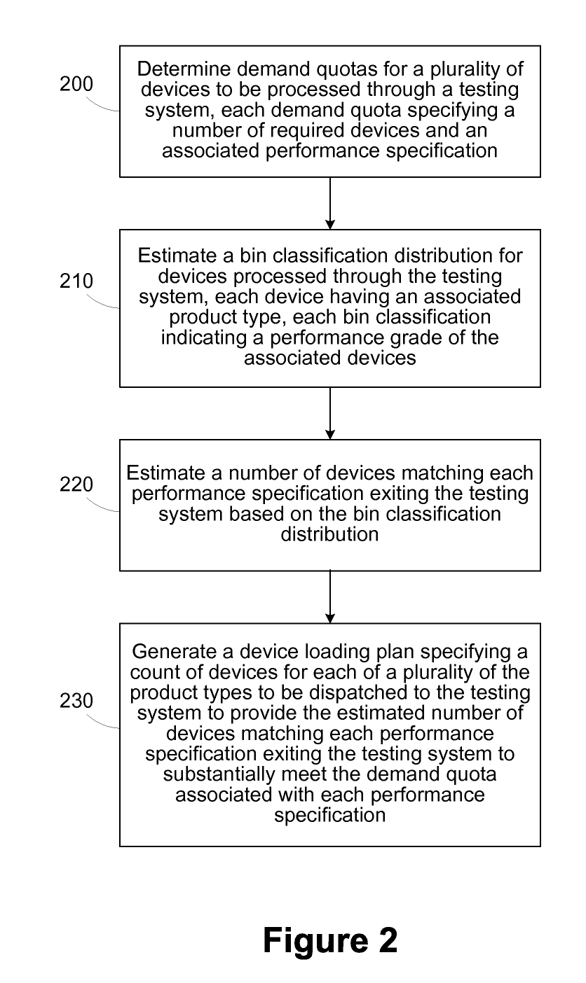

Turning now to FIG. 2, a simplified flow diagram of a method for determining product and test suite loadings for a testing system in accordance with another embodiment of the present subject matter is provided. In method block 200, demand quotas for a plurality of devices to be processed through the testing system are determined. Each demand quota specifies a number of required devices and an associated performance specification. In method block 210, a bin classification distribution for devices processed through the testing system is estimated. Each device has an associated product type. Each bin classification indicates a performance grade of the associated devices. In method block 220, a number of devices matching each performance specification exiting the testing system is estimated based on the bin classification distribution. In method block 230, a device loading plan specifying a count of devices for each of a plurality of the product types to be dispatched to the testing system to provide the estimated number of devices matching each performance specification exiting the testing system to substantially meet the demand quota associated with each performance specification is determined.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosed subject matter. Accordingly, the protection sought herein is as set forth in the claims below.

We claim:

1. A method, comprising:
determining demand quotas for a plurality of devices to be processed through a testing system, each demand quota specifying a number of required devices and an associated performance specification;
estimating a bin classification distribution for devices processed through the testing system, each device having an associated product type, each bin classification indicating a performance grade of the associated devices;
estimating a number of devices matching each performance specification exiting the testing system based on the bin classification distribution; and
generating a device loading plan specifying a count of devices for each of a plurality of the product types to be dispatched to the testing system to provide the estimated number of devices matching each performance specification exiting the testing system to substantially meet the demand quota associated with each performance specification.

2. The method of claim 1, wherein estimating the bin classification distribution comprises estimating the bin classification distribution based on the device loading plan using an iterative approach that varies the device loading plan to substantially meet the demand quota.

3. The method of claim 2, wherein estimating the number of devices matching each performance specification exiting the testing system comprises estimating the number of devices matching each performance specification exiting the testing system based on the bin classification distribution, the device loading plan, and a mapping parameter indicating which particular product types with which particular performance grades may be used to meet a particular performance specification.

4. The method of claim 2, wherein the iterative approach comprises a mixed-integer linear programming approach.

5. The method of claim 1, wherein the testing system is operable to test devices using a plurality of test suites, estimating the bin classification distribution includes determining the bin classification distribution based on the product type and an associated one of the test suites used to test each particular device, and generating the device loading plan includes specifying counts of each product type and an associated test suite.

6. The method of claim 1, wherein estimating the number of devices matching each performance specification exiting the testing system further comprises, for a particular performance specification, subtracting a count of devices that qualify to meet the particular performance specification that are used to fill the demand quota for a different performance specification.

7. The method of claim 1, wherein estimating the number of devices matching each performance specification exiting the testing system further comprises, for a particular performance specification, adding a count of devices that qualify to meet a different performance specification but are used to fill the demand quota for the particular performance specification.

8. The method of claim 1, wherein estimating the number of devices matching each performance specification exiting the testing system further comprises, for a particular performance specification, adding a count of devices that fail to meet a different performance specification but qualify to meet the particular performance specification.

9. The method of claim 1, wherein estimating the bin classification distribution further comprises estimating the bin classification distribution using historical data associated with the testing system.

10. The method of claim 1, wherein the testing system includes at least one hybrid system tester operable to determine performance grades associated with the devices and to test the devices against the performance specifications.

11. A system, comprising a processing device programmed with instructions, that when executed:
determine demand quotas for a plurality of devices to be processed through a testing system, each demand quota specifying a number of required devices and an associated performance specification;
estimate a bin classification distribution for devices processed through the testing system, each device having an associated product type, each bin classification indicating a performance grade of the associated devices;
estimate a number of devices matching each performance specification exiting the testing system based on the bin classification distribution; and
generate a device loading plan specifying a count of devices for each of a plurality of the product types to be dispatched to the testing system to provide the estimated number of devices matching each performance specification exiting the testing system to substantially meet the demand quota associated with each performance specification.

12. The system of claim 11, further comprising at least one tester in the testing system, the tester being operable to determine performance grades associated with the devices and to test the devices against the performance specifications.

13. An apparatus for determining a loading plan for a testing system including at least one testing tool operable to test integrated circuit devices, comprising:
a loading unit operable to determine demand quotas for a plurality of devices to be processed through the testing system, each demand quota specifying a number of required devices and an associated performance specification; estimate a bin classification distribution for devices processed through the testing system, each device having an associated product type, each bin classification indicating a performance grade of the associated devices; estimate a number of devices matching each performance specification exiting the testing system based on the bin classification distribution; and generate a device loading plan specifying a count of devices for each of a plurality of the product types to be dispatched to the testing system to provide the estimated number of devices matching each performance specification exiting the testing system to substantially meet the demand quota associated with each performance specification.

14. The apparatus of claim 13, wherein the loading unit is operable to estimate the bin classification distribution by estimating the bin classification distribution based on the device loading plan using an iterative approach that varies the device loading plan to substantially meet the demand quota.

15. The apparatus of claim 14, wherein the loading unit is operable to estimate the number of devices matching each performance specification exiting the testing system by estimating the number of devices matching each performance specification exiting the testing system based on the bin classification distribution, the device loading plan, and a mapping parameter indicating which particular product types with which particular performance grades may be used to meet a particular performance specification.

16. The apparatus of claim 14, wherein the iterative approach comprises a mixed-integer linear programming approach.

17. The apparatus of claim 13, wherein the testing system is operable to test devices using a plurality of test suites, and the loading unit is operable to estimate the bin classification distribution by determining the bin classification distribution based on the product type and an associated one of the test suites used to test each particular device and generate the device loading plan by specifying counts of each product type and an associated test suite.

18. The apparatus of claim 13, wherein the loading unit is operable to estimate the number of devices matching each performance specification exiting the testing system by, for a particular performance specification, subtracting a count of devices that qualify to meet the particular performance specification that are used to fill the demand quota for a different performance specification.

19. The apparatus of claim 13, wherein the loading unit is operable to estimate the number of devices matching each performance specification exiting the testing system by, for a particular performance specification, adding a count of devices that qualify to meet a different performance specification but are used to fill the demand quota for the particular performance specification.

20. The apparatus of claim 13, wherein the loading unit is operable to estimate the number of devices matching each performance specification exiting the testing system further by, for a particular performance specification, adding a count of devices that fail to meet a different performance specification but qualify to meet the particular performance specification.

21. The apparatus of claim 13, wherein the loading unit is operable to estimate the bin classification distribution by estimating the bin classification distribution using historical data associated with the testing system.

22. A system, comprising:
means for determining demand quotas for a plurality of devices to be processed through a testing system, each demand quota specifying a number of required devices and an associated performance specification;
means for estimating a bin classification distribution for devices processed through the testing system, each device having an associated product type, each bin classification indicating a performance grade of the associated devices;
means for estimating a number of devices matching each performance specification exiting the testing system based on the bin classification distribution; and
means for generating a device loading plan specifying a count of devices for each of a plurality of the product types to be dispatched to the testing system to provide the estimated number of devices matching each performance specification exiting the testing system to substantially meet the demand quota associated with each performance specification.
